(19) United States
(12) Patent Application Publication
(10) Pub. No.: US 2026/0003240 A1
(43) Pub. Date: Jan. 1, 2026

(54) ARRAY SUBSTRATE AND DISPLAY DEVICE

(71) Applicant: Sharp Display Technology Corporation, Kameyama City (JP)

(72) Inventors: Masafumi SUGINO, Kameyama City (JP); Tatsuya KAWASAKI, Kameyama City (JP); Yohei TAKEUCHI, Kameyama City (JP); Kengo HARA, Kameyama City (JP); Hajime IMAI, Kameyama City (JP)

(21) Appl. No.: 19/250,808

(22) Filed: Jun. 26, 2025

(30) Foreign Application Priority Data
Jun. 27, 2024 (JP) 2024-103715

(51) Int. Cl. G02F 1/1368; H10D 86/40

(52) U.S. Cl. CPC G02F 1/1368; H10D 86/423; H10D 86/441

(57) ABSTRACT

An array substrate includes a transistor including a first electrode a semiconductor portion, a second electrode and a third electrode, a first insulating film provided on an upper-layer side of the first electrode and on a lower layer side of the semiconductor portion, a second insulating film provided on an upper-layer side of the second electrode and the third electrode, and a light reflective portion provided on an upper-layer side of the second insulating film, in which the second insulating film is provided with a first recessed portion at a position overlapping none of the first electrode and the semiconductor portion, the light reflective portion includes an overlapping portion overlapping the first electrode and the semiconductor portion and a non-overlapping portion overlapping none of the first electrode and the semiconductor portion, and the non-overlapping portion includes a first filling portion that fills the first recessed portion.

### CROSS-REFERENCE TO RELATED APPLICATIONS

This application claims the benefit of priority to Japanese Patent Application Number 2024-103715 filed on Jun. 27, 2024. The entire contents of the above-identified application are hereby incorporated by reference.

### BACKGROUND

### Technical Field

The techniques disclosed herein relate to array substrates less likely to deteriorate and display devices.

In the related art, an example of a transistor provided in a display device is known, as described in JP 2023-28988 A. A transistor described in JP 2023-28988 A includes a first gate electrode, a second electrode opposed to the first gate electrode, an oxide semiconductor layer provided between the first gate electrode and the second gate electrode, and a source electrode and a drain electrode each connected to the oxide semiconductor layer, in which the oxide semiconductor layer includes a channel formation region, a source region, and a drain region, a light irradiation region whose resistance is reduced by irradiation with light is provided between the channel formation region and the source region and between the channel formation region and the drain region, and the first gate electrode and the second gate electrode have different lengths.

### SUMMARY

In the transistor described in JP 2023-28988 A, when positive charges are repeatedly applied to the gate electrode, a threshold voltage of the transistor shifts in a positive direction over time and characteristics thereof may deteriorate.

The technique described in the present specification has been completed based on the above-described circumstances, and aims to make the characteristics of the transistor be less likely to deteriorate.
(1) An array substrate according to a technique disclosed in the present specification includes a transistor including a first electrode, a semiconductor portion provided on an upper-layer side of the first electrode and disposed to overlap the first electrode, a second electrode provided on an upper-layer side of the semiconductor portion and connected to the semiconductor portion, and a third electrode provided on an upper-layer side of the semiconductor portion, disposed to be spaced apart from the second electrode in a first direction, and connected to the semiconductor portion, a first insulating film provided on an upper-layer side of the first electrode and on a lower layer side of the semiconductor portion, a second insulating film provided on an upper-layer side of the second electrode and the third electrode, and a light reflective portion provided on an upper-layer side of the second insulating film, in which the second insulating film is provided with a first recessed portion at a position overlapping none of the first electrode and the semiconductor portion, the light reflective portion includes an overlapping portion overlapping the first electrode and the semiconductor portion and a non-overlapping portion that is continuous with the overlapping portion and overlaps none of the first electrode and the semiconductor portion, and the non-overlapping portion includes a first filling portion that fills the first recessed portion.
(2) In addition to (1), in the array substrate, the first recessed portion of the second insulating film may be provided to be disposed at a position spaced apart from at least one of the second electrode and the third electrode in the first direction, the non-overlapping portion may include a first non-overlapping portion disposed side by side with the overlapping portion along the first direction, and the first non-overlapping portion may include the first filling portion.
(3) In addition to (2), in the array substrate, a pair of the first recessed portions of the second insulating film may be respectively provided so as to be disposed at a position spaced apart from the second electrode in the first direction and at a position spaced apart from the third electrode in the first direction, a pair of the first non-overlapping portions may be disposed to sandwich the overlapping portion in the first direction, and each of the pair of first non-overlapping portions may include the first filling portion.
(4) In addition to (2) or (3), in the array substrate, the first recessed portion of the second insulating film may be provided to extend along a second direction that is along a main surface of the first electrode and intersects the first direction, and the first filling portion may be provided to extend along the second direction.
(5) In addition to (4), in the array substrate, each of the second electrode and the third electrode may extend along the second direction and may be drawn out of the semiconductor portion.
(6) In addition to any one of (2) to (5), in the array substrate, the semiconductor portion may be shorter than the first electrode in the first direction.
(7) In addition to any one of (2) to (6), in the array substrate, the non-overlapping portion may include a second non-overlapping portion disposed side by side with the overlapping portion along a second direction that is along the main surface of the first electrode and intersects the first direction.
(8) In addition to (7), in the array substrate, the semiconductor portion may be shorter than the first electrode in the second direction.
(9) In addition to any one of (2) to (8), in the array substrate, each of the second electrode and the third electrode may be disposed to overlap none of both ends of the semiconductor portion in the first direction.
(10) In addition to any one of (1) to (9), in the array substrate, the first recessed portion may be provided in the second insulating film to extend therethrough, a second recessed portion may be provided in the first insulating film at a position overlapping the first recessed portion to communicate with the first recessed portion, and the non-overlapping portion may include a second filling portion that is continuous with the first filling portion and fills the second recessed portion.
(11) A display device according to a technique disclosed in the present specification includes the array substrate according to any one of (1) to (10), a display region that displays an image, a non-display region that displays no image, in which a first wiring line is disposed in the display region of the array substrate, a circuit portion connected to the first wiring line is disposed in the non-display region of the array substrate, and the circuit portion includes the transistor.

According to the technique described in the present specification, characteristics of a transistor can be made less likely to deteriorate.

### BRIEF DESCRIPTION OF DRAWINGS

The disclosure will be described with reference to the accompanying drawings, wherein like numbers reference like elements.

FIG. 1 is a plan view of a liquid crystal panel, a driver, and a flexible substrate according to a first embodiment.

FIG. 2 is a cross-sectional view of the liquid crystal panel, the driver, and the flexible substrate according to the first embodiment.

FIG. 3 is a plan view illustrating a pixel arrangement of the liquid crystal panel according to the first embodiment.

FIG. 4 is a cross-sectional view of a pixel TFT provided in a display region of an array substrate constituting the liquid crystal panel according to the first embodiment.

FIG. 5 is a plan view of a non-pixel TFT included in a circuit portion provided in a non-display region of the array substrate according to the first embodiment.

FIG. 6 is a cross-sectional view of the array substrate according to the first embodiment which is taken along line vi-vi in FIG. 5.

FIG. 7 is a cross-sectional view of the array substrate according to the first embodiment which is taken along line vii-vii in FIG. 5.

FIG. 8 is a graph showing a change in a transistor characteristic when a positive polarity voltage is applied to a non-pixel gate electrode in the non-pixel TFT not including a light reflective portion according to the first embodiment.

FIG. 9 is a graph showing a change in a transistor characteristic when a negative polarity voltage is applied to the non-pixel gate electrode without irradiated with light in the non-pixel TFT including the light reflective portion according to the first embodiment.

FIG. 10 is a graph showing a change in a transistor characteristic when a negative polarity voltage is applied to the non-pixel gate electrode while irradiated with light in the non-pixel TFT including the light reflective portion according to the first embodiment.

FIG. 11 is a cross-sectional view taken at the same cutting position as FIG. 6, illustrating a state where a first interlayer insulating film is formed in a fifth step according to the first embodiment.

FIG. 12 is a cross-sectional view taken at the same cutting position as FIG. 6, illustrating a state where a gate insulating film and the first interlayer insulating film are patterned in the fifth step according to the first embodiment.

FIG. 13 is a cross-sectional view taken at the same cutting position as FIG. 6, illustrating a non-pixel TFT in an array substrate according to a second embodiment.

FIG. 14 is a cross-sectional view taken at the same cutting position as FIG. 6, illustrating a non-pixel TFT in an array substrate according to a third embodiment.

FIG. 15 is a plan view of a non-pixel TFT in an array substrate according to a fourth embodiment.

FIG. 16 is a cross-sectional view of an array substrate according to the fourth embodiment that is taken along line xvi-xvi in FIG. 15.

FIG. 17 is a cross-sectional view of a pixel TFT in an array substrate according to a fifth embodiment.

FIG. 18 is a cross-sectional view illustrating a connection position of a source wiring line and an overlapping wiring line in the array substrate according to the fifth embodiment.

### DESCRIPTION OF EMBODIMENTS

### First Embodiment

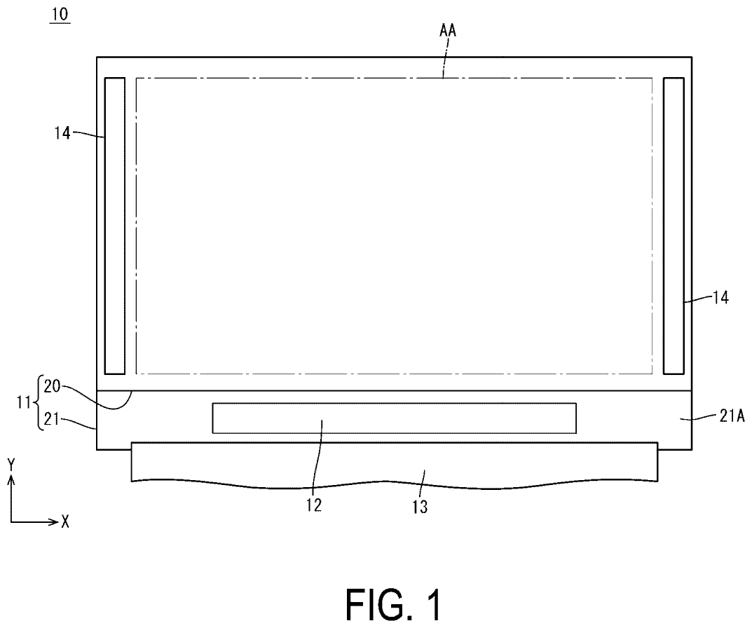

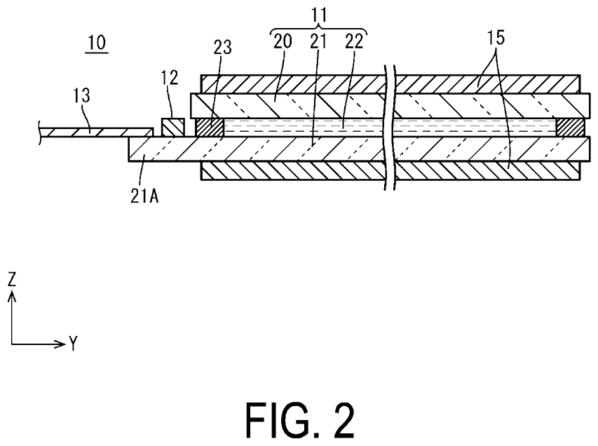

A first embodiment will be described with reference to FIGS. 1 to 12. In present embodiment, a liquid crystal display device 10 is exemplified. Note that some drawings illustrate an X-axis, a Y-axis, and a Z-axis, and directions of these axes are drawn so as to be common in all the drawings. In addition, an upper side of each of FIGS. 2, 4, 6, 7, 11 and 12 is a front side, and a lower side of each of the drawings is a back side.

The liquid crystal display device 10, as illustrated in FIG. 1, includes at least a liquid crystal panel (display device, display panel) 11 that has a horizontally elongated rectangular shape and is capable of displaying an image, and a backlight device (illumination device) that irradiate the liquid crystal panel 11 with light for use in display. The backlight device includes a light source (for example, an LED or the like) disposed on a rear side (back face side) of the liquid crystal panel 11 and configured to emit light having a white color, an optical member configured to impart an optical effect on the light from the light source, thereby converting the light into planar light, and the like. A center-side portion of a main surface of the liquid crystal panel 11 is a display region AA in which an image is displayed. In contrast, a frame-shaped outer peripheral portion surrounding the display region AA of the main surface of the liquid crystal panel 11 is a non-display region NAA in which no image is displayed.

As illustrated in FIG. 1, a circuit portion (peripheral circuit portion, a gate circuit portion) 14 is provided in the non-display region NAA of the liquid crystal panel 11. A pair of circuit portions 14 are disposed to sandwich the display region AA from both sides thereof in the X-axis direction. The circuit portions 14 are provided in a belt-shaped range extending in the Y-axis direction. The circuit portions 14 are configured to supply a scanning signal to a gate wiring line 26 to be described later, and are monolithically provided on an array substrate 21 to be described later. The circuit portion 14 is a gate driver monolithic (GDM) circuit. The circuit portion 14 includes a shift register circuit configured to output a scanning signal at a predetermined timing, a buffer circuit for amplifying the scanning signal, and the like.

The liquid crystal panel 11 will be described with reference to FIG. 2 in addition to FIG. 1. As illustrated in FIGS. 1 and 2, the liquid crystal panel 11 is formed by bonding a pair of substrates 20 and 21 together. Of the pair of substrates 20, 21, the substrate on a front side is a counter substrate 20, and the substrate on a rear side is an array substrate 21. The counter substrate 20 and the array substrate 21 are each formed by layering various films on an inner face side of a glass substrate. A liquid crystal layer 22 is interposed between the pair of substrates 20, 21 and contains liquid crystal molecules, which are substances having optical characteristics that change in accordance with application of an electrical field. A sealing portion 23 that seals the liquid crystal layer 22 is provided to be interposed between outer peripheral ends of the pair of substrates 20 and 21. The sealing portion 23 is formed in a rectangular frame-like shape to surround the liquid crystal layer 22. Polarizers 15 are bonded to the outer face sides of both the substrates 20 and 21, respectively.

As illustrated in FIG. 1 and FIG. 2, the counter substrate 20 has a short side dimension shorter than a short side dimension of the array substrate 21. The counter substrate 20 is bonded to the array substrate 21 with one end in a short side direction (Y-axis direction) aligned with the array substrate 21. Thus, the other end of the array substrate 21 in the short side direction is an exposed portion 21A that protrudes laterally relative to the counter substrate 20 and is exposed. An overall region of this exposed portion 21A is a non-display region NAA, in which a driver 12 for supplying various signals and a flexible substrate 13 are mounted.

The driver 12 includes an LSI chip having a drive circuit therein. The driver 12 is mounted on the exposed portion 21A of the array substrate 21 in a chip-on-glass (COG) manner. The driver 12 processes various signals transmitted by the flexible substrate 13. As illustrated in FIG. 1 and FIG. 2, the driver 12 is adjacent to one side of the display region AA in the Y-axis direction, and is sandwiched between the flexible substrate 13 to be described below and the display region AA. The driver 12 has a horizontally elongated rectangular planar shape. The driver 12 can supply various signals to a source wiring line 27 and the like provided on the array substrate 21. The flexible substrate 13 has a configuration in which a large number of wiring line patterns are formed on a base material made of a synthetic resin material (for example, a polyimide resin or the like) having insulating properties and flexibility. One end of the flexible substrate 13 is connected to the exposed portion 21A of the array substrate 21, and the other end is connected to an external circuit substrate (a control substrate or the like).

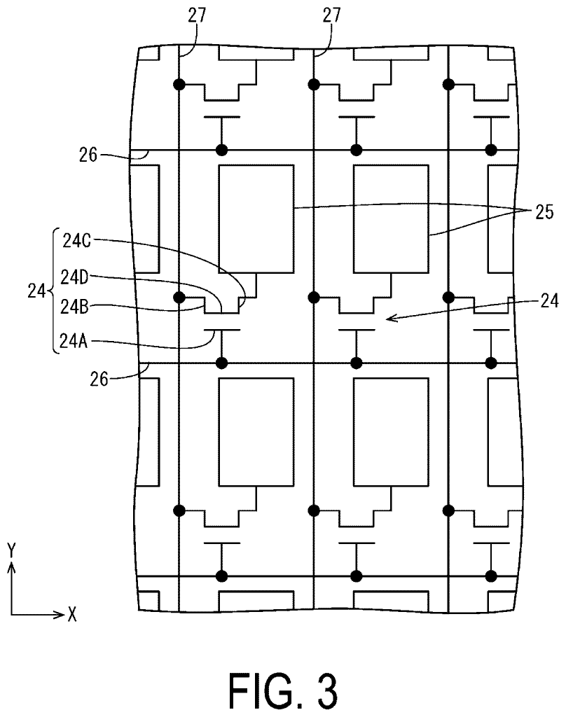

Next, a configuration of the display region AA in the array substrate 21 will be described with reference to FIG. 3. As illustrated in FIG. 3, at least a pixel TFT (pixel transistor, pixel switching element) 24 and a pixel electrode 25 are provided on an inner face side of the display region AA of the array substrate 21. The plurality of pixel TFTs 24 and the plurality of pixel electrodes 25 are provided side by side in a matrix at intervals in the X-axis direction and the Y-axis direction. Gate wiring lines (first wiring line, scanning wiring lines) 26 and source wiring lines (image wiring lines, signal wiring lines) 27 orthogonal to (intersecting) each other are disposed around the pixel TFTs 24 and the pixel electrodes 25. The gate wiring lines 26 extend along the X-axis direction and a plurality of the gate wiring lines 26 are disposed at intervals in the Y-axis direction. The source wiring lines 27 extend along the Y-axis direction and a plurality of the source wiring lines 27 are disposed at intervals in the X-axis direction. The pixel TFT 24 includes a pixel gate electrode 24A that is connected to the gate wiring line 26, a pixel source electrode 24B that is connected to the source wiring line 27, a pixel drain electrode 24C that is connected to the pixel electrode 25, and a pixel semiconductor portion 24D that is connected to the pixel source electrode 24B and the pixel drain electrode 24C and made of a semiconductor material. The pixel TFT 24 is driven on the basis of a scanning signal supplied to the pixel gate electrode 24A by the gate wiring line 26. The scanning signal includes a potential higher than the threshold voltage of the pixel TFT 24. Then, a channel region is generated in the pixel semiconductor portion 24D, so that charges can move between the pixel source electrode 24B and the pixel drain electrode 24C through the channel region. Thus, a potential of an image signal (data signal) supplied to the pixel source electrode 24B through the source wiring line 27 is supplied to the pixel drain electrode 24C through the pixel semiconductor portion 24D. As a result, the pixel electrode 25 is charged to the potential related to the image signal. The pixel electrode 25 is disposed in a region surrounded by the gate wiring line 26 and the source wiring line 27, and has a vertically long substantially rectangular planar shape, for example.

Further, in the display region AA of the counter substrate 20, multiple color filters are provided at positions facing each of the pixel electrodes 25 on the array substrate 21 side. As for the color filters, three colors, namely, R (red), G (green), and B (blue) are repeatedly disposed side by side in a predetermined order, and each pixel (red pixel, green pixel and blue pixel) is constituted together with the pixel electrode 25. A display pixel capable of color display with predetermined gray scale is constituted by three pixels of the red pixel, the green pixel, and the blue pixel. A light blocking portion (black matrix) for preventing color mixing is formed between the respective color filters. Note that alignment films (not illustrated) for aligning the liquid crystal molecules included in the liquid crystal layer 22 are respectively formed on innermost faces (uppermost layers) in contact with the liquid crystal layer 22 of both the substrates 20, 21.

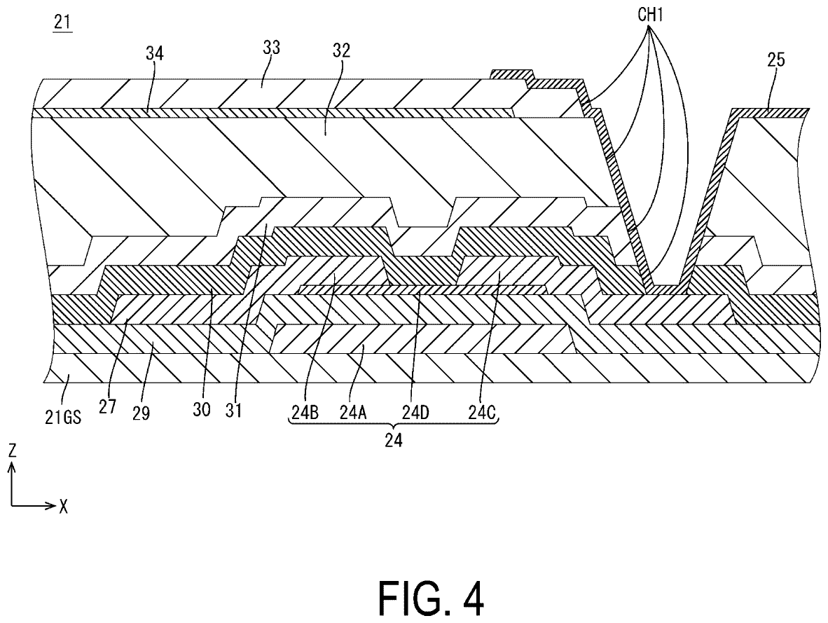

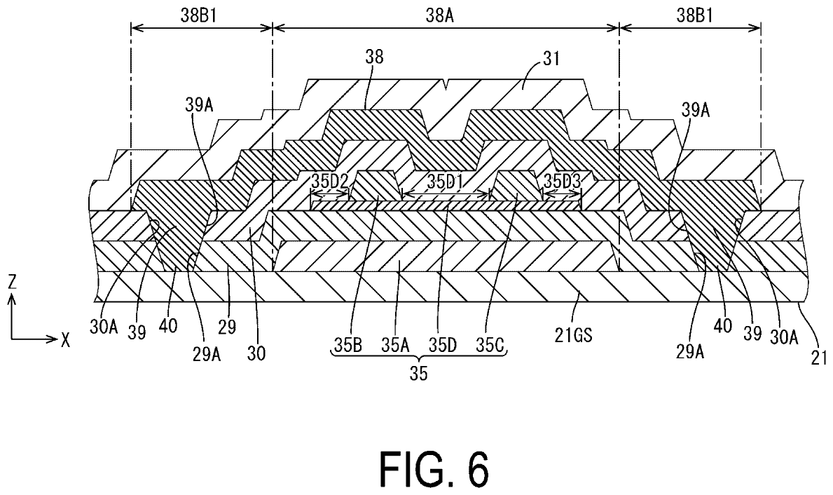

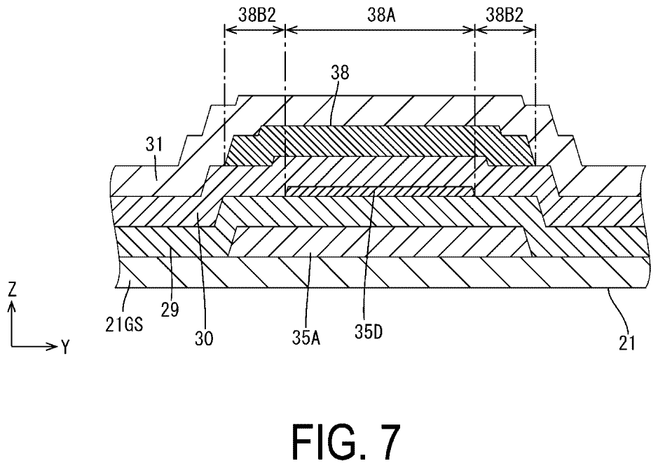

Next, various films layered on the glass substrate (substrate) 21GS of the array substrate 21 will be described in detail with reference to FIG. 4. FIG. 4 illustrates a cross-sectional configuration of the pixel TFT 24. As illustrated in FIG. 4, on a glass substrate 21GS of the array substrate 21, a first metal film (first conductive film), a gate insulating film (first insulating film) 29, a semiconductor film, a second metal film (second conductive film), a first interlayer insulating film (second insulating film) 30, a third metal film (third conductive film), a second interlayer insulating film 31, a flattening film 32, a first transparent electrode film, a third interlayer insulating film 33, a second transparent electrode film, and an alignment film are formed layered in order from the lower layer side (glass substrate 21GS side). The configuration composed of the third metal film of the above films is illustrated in FIGS. 6, 7, and the like.

Each of the first metal film, the second metal film, and the third metal film is a single-layer film made of one type of metal material or a layered film or alloy made of different types of metal materials, and thus has conductivity and light-blocking properties. The first metal film constitutes the gate wiring line 26, the pixel gate electrode 24A of the pixel TFT 24, and the like. The second metal film constitutes the source wiring line 27, the pixel source electrode 24B and the pixel drain electrode 24C of the pixel TFT 24, and the like. The third metal film constitutes a light reflective portion 38 to be described later, and the like. The first transparent electrode film and the second transparent electrode film are composed of a transparent electrode material (for example, indium tin oxide (ITO) or indium zinc oxide (IZO)). The first transparent electrode film constitutes a common electrode 34 to be described later and the like. The second transparent electrode film constitutes the pixel electrode 25 and the like.

The semiconductor film is made of an oxide semiconductor material and constitutes the pixel semiconductor portion 24D of the pixel TFT 24, and the like. The semiconductor film may contain, for example, at least one kind of metal element of In, Ga, and Zn, and for example, an In—Ga—Zn—O based semiconductor (for example, indium gallium zinc oxide) may be used. Here, the In—Ga—Zn—O based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. The In—Ga—Zn—O-based semiconductor used for the semiconductor film may be amorphous or crystalline. The semiconductor film may include another oxide semiconductor in place of the In—Ga—Zn—O based semiconductor. There may be included, for example, an In—Sn—Zn—O based semiconductor (for example, In₂O₃—SnO₂—ZnO; InSnZnO). The In—Sn—Zn—O based semiconductor is a ternary oxide of In (indium), Sn (tin), and Zn (zinc). Alternatively, the oxide semiconductor layer may include an In—W—Zn—O based semiconductor and an In—W—Sn—Zn—O based semiconductor containing tungsten (W), an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, and the like. The oxide semiconductor material of the semiconductor film has a higher resistance value in a state where no voltage is applied (OFF state) than that of a polysilicon semiconductor material. Further, the oxide semiconductor material of the semiconductor film has higher electron mobility than that of an amorphous silicon semiconductor material.

The gate insulating film 29, the first interlayer insulating film 30, the second interlayer insulating film 31, and the third interlayer insulating film 33 are all made of inorganic materials (inorganic resin materials) such as SiO₂ (silicon oxide) and SiNₓ (silicon nitride). The flattening film 32 is an organic insulating film made of, for example, an organic material such as PMMA (acrylic resin). The film thickness of the flattening film 32 is far greater than the film thicknesses of the gate insulating film 29, the first interlayer insulating film 30, the second interlayer insulating film 31, and the third interlayer insulating film 33. The flattening film 32 flattens the inner face of the array substrate 21 (the surface on the liquid crystal layer 22 side).

A configuration of the pixel TFT 24 will be described in detail. As illustrated in FIG. 4, the pixel gate electrode 24A provided in the pixel TFT 24 is formed by widening a portion of the gate wiring line 26 near an intersection with the source wiring line 27. The pixel source electrode 24B provided in the pixel TFT 24 is formed by widening a portion of the source wiring line 27 near an intersection with the gate wiring line 26. The pixel source electrode 24B extends along the X-axis direction, and an end on the opposite side to the source wiring line 27 side is connected to the pixel semiconductor portion 24D. The pixel drain electrode 24C provided in the pixel TFT 24 is disposed at a position spaced apart from the pixel source electrode 24B in the X-axis direction. The pixel drain electrode 24C extends along the X-axis direction and includes one end (left side in FIG. 4, pixel source electrode 24B side) connected to the pixel semiconductor portion 24D and the other end (right side in FIG. 4) connected to the pixel electrode 25. In the first interlayer insulating film 30, the second interlayer insulating film 31, the flattening film 32, and the third interlayer insulating film 33 interposed between the pixel drain electrode 24C and the pixel electrode 25, a pixel contact hole CH1 is communicatively provided at a position overlapping both the pixel drain electrode 24C and the pixel electrode 25. the pixel drain electrode 24C and the pixel electrode 25 are connected to each other through the pixel contact hole CH1.

As illustrated in FIG. 4, the pixel semiconductor portion 24D constituting the pixel TFT 24 is disposed to extend along the X-axis direction. The pixel semiconductor portion 24D has a smaller dimension in the X-axis direction than the pixel gate electrode 24A. The pixel semiconductor portion 24D overlaps the pixel gate electrode 24A through the gate insulating film 29. One end of the pixel semiconductor portion 24D in the X-axis direction is connected to the pixel source electrode 24B. The other end of the pixel semiconductor portion 24D in the X-axis direction is connected to the pixel drain electrode 24C. In a portion of the pixel semiconductor portion 24D that is sandwiched between the pixel source electrode 24B and the pixel drain electrode 24C in the X-axis direction, the channel region is generated when the pixel TFT 24 is driven. The channel region is a portion of the pixel semiconductor portion 24D that overlaps the pixel gate electrode 24A but overlaps none of the pixel source electrode 24B and the pixel drain electrode 24C.

The common electrode 34 composed of the first transparent electrode film has the same size as the display region AA as a whole. As illustrated in FIG. 4, the common electrode 34 is disposed to overlap all the pixel electrodes 25 on a lower layer side through the third interlayer insulating film 33. A common potential (reference potential) is supplied to the common electrode 34. A slit is provided in the pixel electrode 25 that is disposed to overlap the common electrode 34 on an upper-layer side through the third interlayer insulating film 33. When the pixel electrode 25 is charged to a potential based on an image signal transmitted to the source wiring line 27 in association with the driving of the pixel TFT 24 based on a scanning signal transmitted by the gate wiring line 26, a potential difference is generated between the pixel electrode 25 and the common electrode 34. Then, a fringe electrical field (oblique electric field) is generated between an opening edge of the slit in the pixel electrode 25 and the common electrode 34, the fringe electric field including a component in a normal direction with respect to a main surface of the array substrate 21 in addition to a component along the main surface of the array substrate 21. Thus, it is possible to control the alignment state of the liquid crystal molecules included in the liquid crystal layer 22 by using this fringe electrical field, and a predetermined display is performed based on the alignment state of the liquid crystal molecules. That is, an operation mode of the liquid crystal panel 11 according to this embodiment is a fringe field switching (FFS) mode.

Note that the gate insulating film 29 maintains an insulated state between the first metal film on the lower layer side and the semiconductor film and the second metal film on the upper-layer side. For example, an intersection between the gate wiring line 26 composed of the first metal film and the source wiring line 27 composed of the second metal film is maintained in an insulated state by the gate insulating film 29. In addition, in the pixel TFT 24, an overlapping area between the pixel gate electrode 24A composed of the first metal film and the pixel semiconductor portion 24D composed of the semiconductor film is maintained in an insulated state by the gate insulating film 29. The first interlayer insulating film 30 maintains an insulated state between the semiconductor film and the second metal film on the lower layer side and the third metal film on the upper-layer side. The second interlayer insulating film 31 covers the third metal film from the upper-layer side. The second interlayer insulating film 31 and the flattening film 32 maintain the insulated state between the third metal film on the lower layer side and the first transparent electrode film on the upper-layer side. The third interlayer insulating film 33 maintains an insulated state between the first transparent electrode film on the lower layer side and the second transparent electrode film on the upper-layer side. For example, the common electrode 34 composed of the first transparent electrode film and the pixel electrode 25 composed of the second transparent electrode film are maintained in the insulated state from each other by the third interlayer insulating film 33.

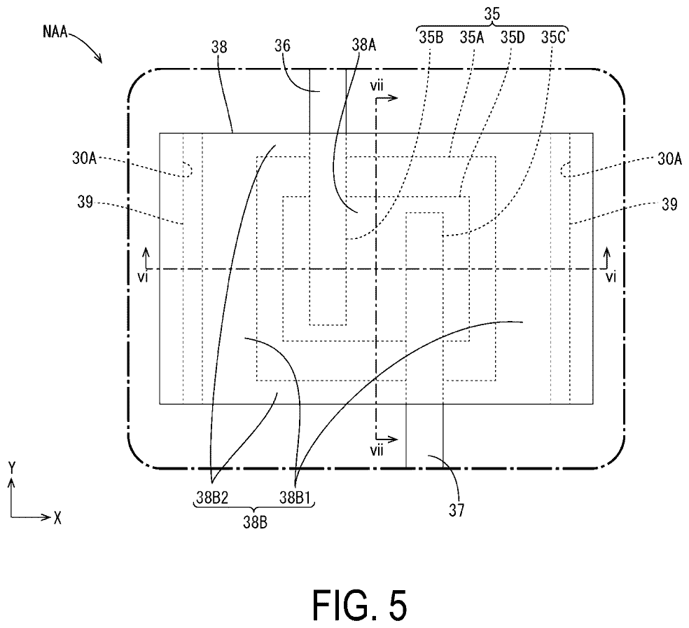

The circuit portion 14 provided in the non-display region NAA of the array substrate 21 is provided with various circuit elements including at least a non-pixel transistor (TFT) 35 illustrated in FIGS. 5 to 7. A configuration of the non-pixel TFT 35 will be described in detail below. As illustrated in FIGS. 5 to 7, the non-pixel TFT 35 includes a non-pixel gate electrode (first electrode) 35A, a non-pixel source electrode (second electrode) 35B, a non-pixel drain electrode (third electrode) 35C, and a non-pixel semiconductor portion (semiconductor portion) 35D. Similarly to the pixel gate electrode 24A, the non-pixel gate electrode 35A is composed of part of the first metal film. Similarly to the pixel source electrode 24B and the pixel drain electrode 24C, a non-pixel source electrode 35B and a non-pixel drain electrode 35C are each composed of part of the second metal film. Similarly to the pixel semiconductor portion 24D, the non-pixel semiconductor portion 35D is composed of part of the semiconductor film.

As illustrated in FIG. 5, the non-pixel gate electrode 35A provided in the non-pixel TFT 35 has a horizontally long square shape in a plan view. A wiring line (not illustrated) provided in the circuit portion 14 is connected to the non-pixel gate electrode 35A, and a signal for driving the non-pixel gate electrode TFT 35 is supplied through the wiring line. The non-pixel source electrode 35B provided in the non-pixel TFT 35 extends along the Y-axis direction, and includes one end connected to the non-pixel semiconductor portion 35D and the other end drawn to the outside of the non-pixel semiconductor portion 35D and connected to a first circuit wiring line 36 provided in the circuit portion 14. A predetermined signal is input to the non-pixel source electrode 35B through the first circuit wiring line 36. Similarly to the non-pixel source electrode 35B, the first circuit wiring line 36 is composed of part of the second metal film. The non-pixel source electrode 35B is disposed so as to be biased toward one end (the left side in FIG. 5) of the non-pixel semiconductor portion 35D in the X-axis direction. Specifically, the non-pixel source electrode 35B is disposed closer to the non-pixel drain electrode 35C side (on the right side in FIG. 5) to be described later than one end position (the left end position in FIG. 5) of the non-pixel semiconductor portion 35D.

As illustrated in FIG. 5, the non-pixel drain electrode 35C provided in the non-pixel TFT 35 extends along the Y-axis direction and includes one end connected to the non-pixel semiconductor portion 35D and the other end drawn to the outside of the non-pixel semiconductor portion 35D and connected to a second circuit wiring line 37 provided in the circuit portion 14. The non-pixel drain electrode 35C is drawn out toward the opposite side (lower side in FIG. 5) to the non-pixel source electrode 35B in the Y-axis direction. A signal from the non-pixel source electrode 35B is output from the non-pixel drain electrode 35C to the second circuit wiring line 37. Similarly to the non-pixel drain electrode 35C, the second circuit wiring line 37 is composed of part of the second metal film. The non-pixel drain electrode 35C is disposed at a position spaced apart from the non-pixel source electrode 35B in the X-axis direction (the first direction). The non-pixel drain electrode 35C is disposed so as to be biased toward the other end (the right side in FIG. 5) of the non-pixel semiconductor portion 35D in the X-axis direction. Specifically, the non-pixel drain electrode 35C is disposed on the non-pixel source electrode 35B side (the left side in FIG. 5) than the other end position (the right end position in FIG. 5) of the non-pixel semiconductor portion 35D.

As illustrated in FIG. 5, similarly to the non-pixel gate electrode 35A, the non-pixel semiconductor portion 35D constituting the non-pixel TFT 35 has a horizontally long square shape in a plan view. The non-pixel semiconductor portion 35D has smaller dimensions in the X-axis direction and the Y-axis direction than the non-pixel gate electrode 35A. The non-pixel semiconductor portion 35D is disposed at a position concentric with the non-pixel gate electrode 35A in the X-axis direction and the Y-axis direction. Thus, as illustrated in FIGS. 6 and 7, an overall region of the non-pixel semiconductor portion 35D overlaps the non-pixel gate electrode 35A through the gate insulating film 29. In other words, the overall region of the non-pixel semiconductor portion 35D is covered with the non-pixel gate electrode 35A from the back surface side (back side, backlight device side). One end side portion of the non-pixel semiconductor portion 35D in the X-axis direction is connected to the non-pixel source electrode 35B. The other end side portion of the non-pixel semiconductor portion 35D in the X-axis direction is connected to the non-pixel drain electrode 35C. A portion of the non-pixel semiconductor portion 35D that is sandwiched between the non-pixel source electrode 35B and the non-pixel drain electrode 35C in the X-axis direction serves as a channel forming portion 35D1 in which the channel region is generated when the non-pixel TFT 35 is driven. The channel forming portion 35D1 is a portion of the non-pixel semiconductor portion 35D that overlaps the non-pixel gate electrode 35A but overlaps none of the non-pixel source electrode 35B and the non-pixel drain electrode 35C between the non-pixel source electrode 35B and the non-pixel drain electrode 35C in the X-axis direction. Both ends 35D2 and 35D3 of the non-pixel semiconductor portion 35D in the X-axis direction overlaps none of the non-pixel source electrode 35B and the non-pixel drain electrode 35C, respectively.

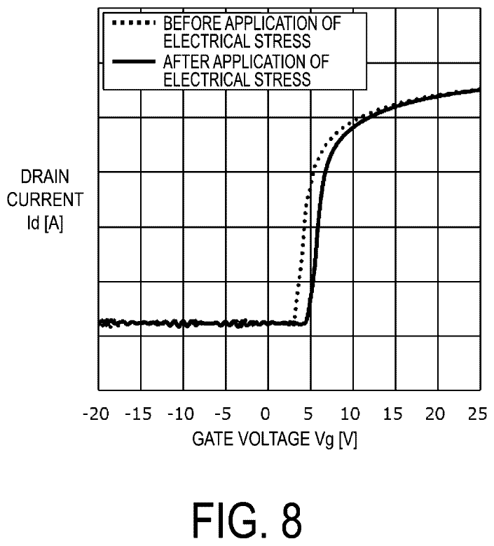

In the non-pixel TFT 35 having the above-described configuration, when a voltage equal to or higher than the threshold voltage is applied to the non-pixel gate electrode 35A, a channel region is generated in the channel forming portion 35D1 of the non-pixel semiconductor portion 35D disposed to overlap the non-pixel gate electrode 35A on an upper-layer side through the gate insulating film 29, and charges can move between the non-pixel source electrode 35B and the non-pixel drain electrode 35C through the channel region. By the way, since the non-pixel TFT 35 is a circuit element constituting the circuit portion 14, a positive polarity voltage is predominantly applied to the non-pixel gate electrode 35A. When the positive polarity voltage is repeatedly applied to the non-pixel gate electrode 35A, as shown in FIG. 8, the threshold voltage of the non-pixel gate electrode TFT 35 shifts in the positive direction, and the characteristics of the non-pixel gate electrode TFT 35 may deteriorate. FIG. 8 is a graph showing a change in a transistor characteristic when a positive polarity voltage is applied to the non-pixel gate electrode in the non-pixel TFT not including the light reflective portion 38 to be described below. The vertical axis of the graph of FIG. 8 is a drain current Id (unit: “A”) that is a current flowing through the channel region of the non-pixel semiconductor portion, and the horizontal axis of the graph of FIG. 8 is a gate voltage Vg (unit: “V”) that is a voltage applied to the non-pixel gate electrode. In FIG. 8, the transistor characteristic when the positive polarity gate voltage Vg is applied for the first time (the state before an electrical stress is applied) is indicated by a broken line, and the transistor characteristic when the positive polarity gate voltage Vg is repeatedly applied and the electrical stress is applied is indicated by a solid line. According to FIG. 8, it can be seen that the transistor characteristic in the state where the electrical stress is applied shifts in the positive direction (right side in FIG. 8) with respect to the transistor characteristic in the state before the electrical stress is applied.

Thus, as illustrated in FIGS. 5 to 7, the array substrate 21 according to the present embodiment is provided with a light reflective portion 38 disposed so as to cover the non-pixel TFT 35 from the upper-layer side. The light reflective portion 38 is composed of the third metal film and has high light reflectivity and light-blocking properties. The light reflective portion 38 is disposed on the upper-layer side of the first interlayer insulating film 30. The light reflective portion 38 is covered and protected by the second interlayer insulating film 31 disposed on the upper-layer side of the light reflective portion 38. In the present embodiment, the light reflective portion 38 is not connected to and electrically isolated from the electrodes 35A to 35C and the like constituting the non-pixel TFT 35.

As illustrated in FIGS. 5 to 7, the light reflective portion 38 includes an overlapping portion 38A that overlaps the non-pixel gate electrode 35A and the non-pixel semiconductor portion 35D, and a non-overlapping portion 38B that is continuous with the overlapping portion 38A and overlaps none of the non-pixel gate electrode 35A and the non-pixel semiconductor portion 35D. Specifically, the light reflective portion 38 has a horizontally long square shape in a plan view. The light reflective portion 38 has larger dimensions in the X-axis direction and the Y-axis direction than the non-pixel gate electrode 35A. The light reflective portion 38 is disposed at a position concentric with the non-pixel semiconductor portion 35D and the non-pixel gate electrode 35A in the X-axis direction and the Y-axis direction. Thus, a center-side portion of the light reflective portion 38 is the overlapping portion 38A that overlaps the non-pixel semiconductor portion 35D and the non-pixel gate electrode 35A. The overlapping portion 38A is a portion that overlaps both the non-pixel semiconductor portion 35D and the non-pixel gate electrode 35A, and includes a portion that overlaps a portion of the non-pixel gate electrode 35A that overlaps none of the non-pixel semiconductor portion 35D. On the other hand, an outer peripheral end side portion of the light reflective portion 38 surrounding the overlapping portion 38A is the non-overlapping portion 38B that overlaps none of the non-pixel semiconductor portion 35D and the non-pixel gate electrode 35A. The non-overlapping portion 38B is a portion that overlaps none of the non-pixel semiconductor portion 35D and the non-pixel gate electrode 35A, and also overlaps none of a portion of the non-pixel gate electrode 35A that overlaps none of the non-pixel semiconductor portion 35D. As described above, the light reflective portion 38 covers the overall regions of the non-pixel semiconductor portions 35D and the non-pixel gate electrode 35A from the upper-layer side, and surrounds and covers peripheries of the non-pixel semiconductor portion 35D and the non-pixel gate electrode 35A from the upper-layer side. Thus, when light from the backlight device is radiated to the array substrate 21 from the back side (the lower layer side of the non-pixel gate electrode 35A), by reflecting the light by the non-overlapping portion 38B of the light reflective portion 38, the light can be directed to the non-pixel semiconductor portion 35D. This makes it possible to shift the threshold voltage of the non-pixel TFT 35 in the negative direction, thereby making the characteristics of the non-pixel TFT 35 less likely to deteriorate.

In the present embodiment, as illustrated in FIG. 6, the first interlayer insulating film 30 is provided with a first recessed portion 30A at a position overlapping none of the non-pixel gate electrode 35A and the non-pixel semiconductor portion 35D. The non-overlapping portion 38B includes a first filling portion 39 that fills the first recessed portion 30A. In the present embodiment, the first recessed portion 30A is provided so as to extend through the first interlayer insulating film 30, and the first filling portion 39 fills the entire depth of the first recessed portion 30A that is a through hole. The first filling portion 39 that fills the first recessed portion 30A is disposed so as to protrude from a surface of the first interlayer insulating film 30 toward the lower layer side. Thus, the light from the backlight device can be efficiently reflected by the first filling portion 39 that fills the first recessed portion 30A to be directed to the non-pixel semiconductor portion 35D. The light reflected by the non-overlapping portion 38B including the first filling portion 39 is repeatedly reflected between the overlapping portion 38A of the light reflective portion 38 that overlaps the non-pixel gate electrode 35A and the non-pixel gate electrode 35A, thereby efficiently radiated to the channel forming portion 35D1 of the non-pixel semiconductor portion 35D. This makes it possible to efficiently shift the threshold voltage of the non-pixel TFT 35 in the negative direction, thereby making the characteristics of the non-pixel TFT 35 less likely to deteriorate. In particular, in the present embodiment, since the non-pixel semiconductor portion 35D is shorter than the non-pixel gate electrode 35A in the X-axis direction, the light from the backlight device is less likely to be directly radiated to the non-pixel semiconductor portion 35D. In this regard, by reflecting the light from the backlight device by a first non-overlapping portion 38B1 including the first filling portion 39, it is possible to efficiently radiate the reflected light to the channel forming portion 35D1 of the non-pixel semiconductor portion 35D. This makes it possible to more efficiently shift the threshold voltage of the non-pixel TFT 35 in the negative direction.

As illustrated in FIG. 6, in the first interlayer insulating film 30, a pair of the first recessed portions 30A are respectively provided so as to be disposed at a position spaced apart from the non-pixel source electrode 35B on the opposite side to the non-pixel drain electrode 35C side in the X-axis direction and at a position spaced apart from the non-pixel drain electrode 35C on the opposite side to the non-pixel source electrode 35B side in the X-axis direction. On the other hand, the non-overlapping portion 38B includes the first non-overlapping portion 38B1 disposed side by side with the overlapping portion 38A along the X-axis direction. The first non-overlapping portions 38B1 are disposed side by side with the overlapping portion 38A respectively on one side in the X-axis direction and on the other side in the X-axis direction. That is, a pair of the first non-overlapping portions 38B1 are disposed so as to sandwich the overlapping portion 38A in the X-axis direction. The first filling portion 39 is included in each of the pair of first non-overlapping portions 38B1. The pair of first filling portions 39 fill the pair of first recessed portions 30A, respectively, in the first interlayer insulating film 30. According to such a configuration, the light radiated from the backlight device to the array substrate 21 is reflected by the pair of non-overlapping portions 38B sandwiching the overlapping portion 38A in the X-axis direction. Since the pair of non-overlapping portions 38B include the first filling portions 39 that fill the pair of first recessed portions 30A, the light reflected by the pair of first filling portions 39 can be guided toward the non-pixel source electrode 35B and the non-pixel drain electrode 35C side along the X-axis direction, and can be more efficiently radiated to the channel forming portion 35D1 of the non-pixel semiconductor portion 35D from both sides. This makes it possible to more efficiently shift the threshold voltage of the non-pixel TFT 35 in the negative direction.

As illustrated in FIGS. 5 and 6, the first interlayer insulating film 30 is provided with the first recessed portions 30A extending along the Y-axis direction (a second direction that is along the main surface of the non-pixel gate electrode 35A and intersects the first direction). Similarly to the first recessed portion 30A, the first filling portion 39 is provided so as to extend along the Y-axis direction. The first recessed portion 30A and the first filling portion 39 are provided over the entire length of the light reflective portion 38 in the Y-axis direction. Thus, the first recessed portion 30A and the first filling portion 39 are present laterally spaced apart from the non-pixel semiconductor portion 35D over the entire length in the Y-axis direction. With this configuration, since the first filling portion 39 that fills the first recessed portion 30A has a surface 39A along the Y-axis direction, the light is more efficiently reflected by the surface 39A to be radiated to the channel forming portion 35D1 of the non-pixel semiconductor portion 35D. This makes it possible to more efficiently shift the threshold voltage of the non-pixel TFT 35 in the negative direction. On the other hand, as described above, each of the non-pixel source electrode 35B and the non-pixel drain electrode 35C extends along the Y-axis direction and is drawn to the outside of the non-pixel semiconductor portion 35D. As described above, since the non-pixel source electrode 35B and the non-pixel drain electrode 35C extend in parallel with the first recessed portion 30A and are drawn out to the outside of the non-pixel semiconductor portion 35D, it is possible to prevent the non-pixel source electrode 35B and the non-pixel drain electrode 35C from physically interfering with the first recessed portion 30A and the first filling portion 39.

As illustrated in FIGS. 5 and 7, the non-overlapping portion 38B includes second non-overlapping portions 38B2 disposed side by side with the overlapping portion 38A along the Y-axis direction. The second non-overlapping portions 38B2 are disposed side by side with the overlapping portion 38A respectively on one side in the Y-axis direction and on the other side in the Y-axis direction. That is, a pair of the second non-overlapping portions 38B2 are disposed so as to sandwich the overlapping portion 38A in the Y-axis direction. With this configuration, the light can be reflected by also the second non-overlapping portion 38B2 in addition to the first non-overlapping portion 38B1 including the first filling portion 39 to be caused to travel along the Y-axis direction and can be efficiently radiated to the channel forming portion 35D1 of the non-pixel semiconductor portion 35D. This makes it possible to efficiently shift the threshold voltage of the non-pixel TFT 35 in the negative direction. In particular, in the present embodiment, since the non-pixel semiconductor portion 35D is shorter than the non-pixel gate electrode 35A in the Y-axis direction, the light from the backlight device is less likely to be directly radiated to the non-pixel semiconductor portion 35D. In this regard, by reflecting the light radiated from the lower layer side of the non-pixel gate electrode 35A by the second non-overlapping portion 38B2, the reflected light can be caused to travel along the Y-axis direction and can be efficiently radiated to the channel forming portion 35D1 of the non-pixel semiconductor portion 35D. This makes it possible to more efficiently shift the threshold voltage of the non-pixel TFT 35 in the negative direction.

As illustrated in FIG. 6, in the gate insulating film 29 disposed to the first interlayer insulating film 30 on the lower layer side, a second recessed portion 29A is provided at a position overlapping the first recessed portion 30A penetrating the first interlayer insulating film 30. The second recessed portion 29A communicates with the first recessed portion 30A. The non-overlapping portion 38B includes a second filling portion 40 that is continuous with the first filling portion 39 and fills the second recessed portion 29A. In the present embodiment, the second recessed portion 29A is provided so as to extend through the gate insulating film 29, and the second filling portion 40 fills the entire depth of the second recessed portion 29A that is a through hole. As described above, the second filling portion 40 that fills the second recessed portion 29A is disposed so as to protrude from a surface of the gate insulating film 29 toward the lower layer side. Thus, the light from the backlight device can be efficiently reflected by the second filling portion 40 that fills the second recessed portion 29A together with the first filling portion 39 to be directed to the non-pixel semiconductor portion 35D. This makes it possible to more efficiently shift the threshold voltage of the non-pixel TFT 35 in the negative direction.

As illustrated in FIGS. 5 to 7, similarly to the first recessed portions 30A, a pair of the second recessed portions 29A are respectively provided so as to be disposed at a position spaced apart from the non-pixel source electrode 35B in the X-axis direction and at a position spaced apart from the non-pixel drain electrode 35C in the X-axis direction, and both are provided so as to extend along the Y-axis direction. Similarly to the first filling portions 39, a pair of the second filling portions 40 are disposed so as to sandwich the overlapping portion 38A in the X-axis direction, and are each provided so as to extend along the Y-axis direction.

As illustrated in FIGS. 5 and 6, the non-pixel source electrode 35B and the non-pixel drain electrode 35C are disposed so as to overlap none of both ends 35D2 and 35D3, respectively, of the non-pixel semiconductor portion 35D in the X-axis direction. According to such a configuration, both ends 35D2 and 35D3 of the non-pixel semiconductor portion 35D in the X-axis direction are exposed without being covered by the non-pixel source electrode 35B and the non-pixel drain electrode 35C, respectively. Thus, the light reflected by the first non-overlapping portion 38B1 including the first filling portion 39 can be directly radiated to the ends 35D2 and 35D3 of the non-pixel semiconductor portion 35D in the X-axis direction. This makes it possible to efficiently radiate the light to the channel forming portion 35D1 of the non-pixel semiconductor portion 35D.

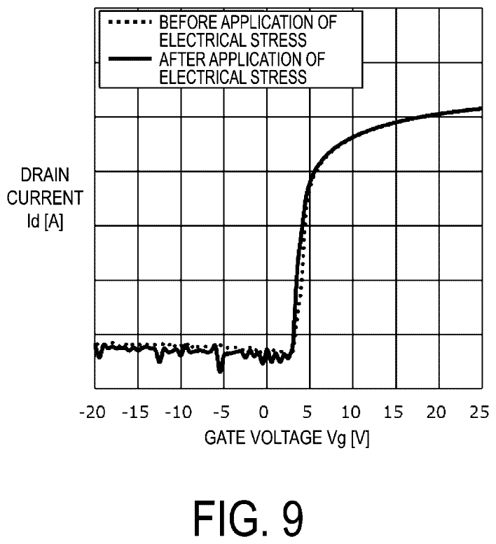

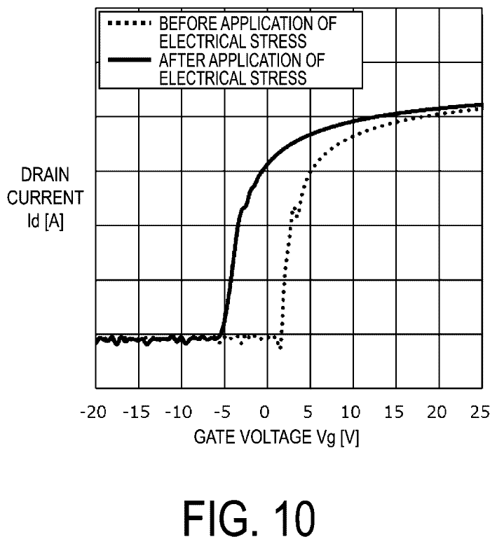

FIGS. 9 and 10 are graphs each showing a change in a transistor characteristic when a negative polarity voltage is applied to the non-pixel gate electrode 35A in the non-pixel TFT 35 including the above-described light reflective portion 38. FIG. 9 is a graph in the case where the light from the backlight device is not radiated to the array substrate 21. FIG. 10 is a graph in the case where the light from the backlight device is radiated to the array substrate 21, and the illuminance of the light radiated to the array substrate 21 is about 30001x. Similarly to FIG. 8, the vertical axis of each of the graphs of FIGS. 9 and 10 is the drain current Id (unit: “A”) that is a current flowing through the channel region of the non-pixel semiconductor portion 35D, and, similarly to FIG. 8, the horizontal axis of each of the graphs of FIGS. 9 and 10 is the gate voltage Vg (unit: “V”) that is a voltage applied to the non-pixel gate electrode 35A. In each of FIGS. 9 and 10, the transistor characteristic when the negative polarity gate voltage Vg is applied for the first time is indicated by a broken line, and the transistor characteristic when the negative polarity gate voltage Vg is repeatedly applied and the electrical stress is applied is indicated by a solid line.

According to FIG. 9, it can be seen that in the case where the light is not radiated, the transistor characteristic in the state where the electrical stress is applied hardly shifts with respect to the transistor characteristic in the state before the electrical stress is applied. This means that even when the negative polarity gate voltage Vg is applied, the transistor characteristic of the non-pixel TFT 35 does not change so much. According to FIG. 10, it can be seen that in the case where light is radiated, the transistor characteristic in the state where the electrical stress is applied greatly shifts in the negative direction (left side in FIG. 10) with respect to the transistor characteristic in the state before the electrical stress is applied. It is presumed that the shift amount of the transistor characteristic shown in FIG. 10 is a result of acceleration by radiation of the light to shift the transistor characteristic in the negative direction due to repeated application of the negative polarity gate voltage Vg. Thus, in the non-pixel TFT 35 including the light reflective portion 38 according to the present embodiment, even when the positive polarity voltage is repeatedly applied to the non-pixel gate electrode 35A, when the light from the backlight device is radiated, by reflecting the light by the first filling portion 39 and the second filling portion 40 of the light reflective portion 38, the light can be efficiently radiated to the channel forming portion 35D1 of the non-pixel semiconductor portion 35D, thereby suppressing the shift of the transistor characteristic in the positive direction.

The liquid crystal panel 11 according to the present embodiment has the above-described structure, and a manufacturing method thereof will be subsequently described. The manufacturing method of the liquid crystal panel 11 includes a counter substrate manufacturing step (counter substrate manufacturing step) of manufacturing the counter substrate 20, an array substrate manufacturing step (array substrate manufacturing step) of manufacturing the array substrate 21, and a bonding step of bonding the manufactured counter substrate 20 and the array substrate 21 together. Hereinafter, among the above steps, the array substrate manufacturing step will be described.

The array substrate manufacturing step includes at least a first step in which the first metal film is formed and patterned, a second step in which the gate insulating film 29 is formed, a third step in which the semiconductor film is formed and patterned, a fourth step in which the second metal film is formed and patterned, a fifth step in which the first interlayer insulating film 30 is formed and patterned, a sixth step in which the third metal film is formed and patterned, a seventh step in which the second interlayer insulating film 31 and the flattening film 32 are formed. an eighth step in which the first transparent electrode film is formed and patterned, a ninth step in which the third interlayer insulating film 33 is formed and patterned, a tenth step in which the second transparent electrode film is formed and patterned, and an eleventh step in which the alignment film is formed.

The term “patterning” described above means a process of a film based on a general photolithography method. Specifically, the process, that is, the patterning of a film to be processed is performed by performing the film formation of a photoresist film on the film to be processed, exposing the photoresist film with an exposure device through a photomask having a predetermined opening pattern, and then developing the photoresist film, and performing etching through the developed photoresist film.

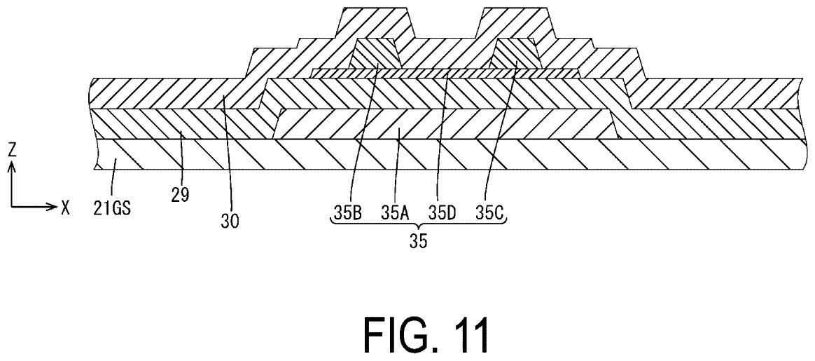

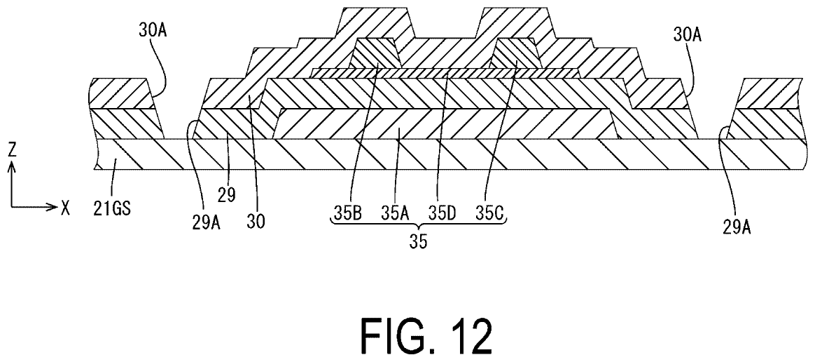

Hereinafter, the fifth step included in the array substrate manufacturing step will be described using FIG. 11 and FIG. 12. When the fifth step is performed, the first interlayer insulating film 30 is formed, and in the circuit portion 14, as illustrated in FIG. 11, the non-pixel source electrode 35B and the non-pixel drain electrode 35C composed of the second metal film are covered with the first interlayer insulating film 30 from the upper-layer side. The formed first interlayer insulating film 30 is patterned together with the gate insulating film 29 by the general photolithography method described above. When the patterning is performed, as illustrated in FIG. 12, the first interlayer insulating film 30 is selectively etched to form the first recessed portions 30A. Further, a portion of the gate insulating film 29 exposed through the first recessed portion 30A is selectively etched to form the second recessed portions 29A communicating with the first recessed portion 30A. A pair of the first recessed portions 30A provided in the first interlayer insulating film 30 extend through the first interlayer insulating film 30, and are disposed at positions sandwiching the non-pixel semiconductor portion 35D from both sides in the X-axis direction. A pair of the second recessed portions 29A provided in the gate insulating film 29 extend through the gate insulating film 29, and are disposed at positions sandwiching the non-pixel semiconductor portion 35D from both sides in the X-axis direction. Thereafter, when the sixth step is performed and the formed third metal film is patterned, the light reflective portion 38 is provided in the circuit portion 14 as illustrated in FIG. 6. The first filling portion 39 included in the non-overlapping portion 38B of the light reflective portion 38 fills the first recessed portion 30A, and the second filling portion 40 fills the second recessed portion 29A.

As described above, the array substrate 21 according to the present embodiment includes the non-pixel transistor (TFT) 35 including the non-pixel gate electrode (first electrode) 35A, the non-pixel semiconductor portion (semiconductor portion) 35D provided on the upper-layer side of the non-pixel gate electrode 35A and disposed to overlap the non-pixel gate electrode 35A, the non-pixel source electrode (second electrode) 35B provided on the upper-layer side of the non-pixel semiconductor portion 35D and connected to the non-pixel semiconductor portion 35D, and the non-pixel drain electrode (third electrode) 35C provided on the upper-layer side of the non-pixel semiconductor portion 35D, disposed spaced apart from the non-pixel source electrode 35B in the first direction, and connected to the non-pixel semiconductor portion 35D, the gate insulating film (first insulating film) 29 provided on the upper-layer side of the non-pixel gate electrode 35A and the lower layer side of the non-pixel semiconductor portion 35D, the first interlayer insulating film (second insulating film) 30 provided on the upper-layer side of the non-pixel source electrode 35B and the non-pixel drain electrode 35C, and the light reflective portion 38 provided on the upper-layer side of the first interlayer insulating film 30, in which the first interlayer insulating film 30 is provided with the first recessed portion 30A at the position overlapping none of the non-pixel gate electrode 35A and the non-pixel semiconductor portion 35D, the light reflective portion 38 includes the overlapping portion 38A that overlaps the non-pixel gate electrode 35A and the non-pixel semiconductor portion 35D, and the non-overlapping portion 38B that is continuous with the overlapping portion 38A and overlaps none of the non-pixel gate electrode 35A and the non-pixel semiconductor portion 35D, and the non-overlapping portion 38B includes the first filling portion 39 that fills the first recessed portion 30A.

When the voltage equal to or higher than the threshold voltage of the non-pixel TFT 35 is applied to the non-pixel gate electrode 35A, the channel region is generated in the non-pixel semiconductor portion 35D disposed to overlap the non-pixel gate electrode 35A on the upper-layer side through the gate insulating film 29, and charges can move between the non-pixel source electrode 35B and the non-pixel drain electrode 35C through the channel region. When a positive voltage is repeatedly applied to the non-pixel gate electrode 35A, the threshold voltage of the non-pixel gate electrode TFT 35 may shift in the positive direction and the characteristics of the non-pixel gate electrode TFT 35 may deteriorate.

In this regard, since the light reflective portion 38 provided on the upper-layer side of the non-pixel source electrode 35B includes the non-overlapping portion 38B that overlaps none of the non-pixel gate electrode 35A and the non-pixel semiconductor portion 35D, when light is radiated from the lower layer side of the non-pixel gate electrode 35A, the light can be reflected by the non-overlapping portion 38B of the light reflective portion 38 to be directed to the non-pixel semiconductor portion 35D. In addition, in the first interlayer insulating film 30 provided on the upper-layer side of the non-pixel source electrode 35B and the non-pixel drain electrode 35C, the first recessed portion 30A is provided at a position overlapping none of the non-pixel gate electrode 35A and the non-pixel semiconductor portion 35D, and the non-overlapping portion 38B of the light reflective portion 38 includes the first filling portion 39 that fills the first recessed portion 30A. Since the first filling portion 39 that fills the first recessed portion 30A is disposed so as to protrude from a surface of the first interlayer insulating film 30 toward the lower layer side, the light radiated from the lower layer side of the non-pixel gate electrode 35A can be efficiently reflected to be directed to the non-pixel semiconductor portion 35D. The light reflected by the non-overlapping portion 38B including the first filling portion 39 is repeatedly reflected between the overlapping portion 38A of the light reflective portion 38 that overlaps the non-pixel gate electrode 35A and the non-pixel gate electrode 35A, thereby efficiently radiated to a portion of the non-pixel semiconductor portion 35D that serves as the channel region (portion sandwiched between the non-pixel source electrode 35B and the non-pixel drain electrode 35C). This makes it possible to efficiently shift the threshold voltage of the non-pixel TFT 35 in the negative direction, thereby making the characteristics of the non-pixel TFT 35 less likely to deteriorate.

In the first interlayer insulating film 30, the first recessed portion 30A is provided to be disposed at a position spaced apart from at least one of the non-pixel source electrode 35B and the non-pixel drain electrode 35C in the first direction, the non-overlapping portion 38B includes the first non-overlapping portions 38B1 disposed side by side with the overlapping portion 38A along the first direction, and the first non-overlapping portion 38B1 includes the first filling portion 39. According to such a configuration, the light reflected by the first non-overlapping portion 38B1 including the first filling portion 39 can be guided to the non-pixel source electrode 35B and the non-pixel drain electrode 35C side along the first direction, and can be efficiently radiated to the portion of the non-pixel semiconductor portion 35D that serves as the channel region. This makes it possible to efficiently shift the threshold voltage of the non-pixel TFT 35 in the negative direction.

In addition, in the first interlayer insulating film 30, a pair of the first recessed portions 30A are respectively provided so as to be disposed at a position spaced apart from the non-pixel source electrode 35B in the first direction and at a position spaced apart from the non-pixel drain electrode 35C in the first direction, a pair of the first non-overlapping portions 38B1 are disposed so as to sandwich the overlapping portion 38A in the first direction, and each of the pair of first non-overlapping portions 38B1 includes the first filling portion 39. According to such a configuration, the light reflected by the first non-overlapping portion 38B1 including the first filling portion 39 can be efficiently radiated to the portion of the non-pixel semiconductor portion 35D that serves as the channel region from both sides in the first direction. This makes it possible to more efficiently shift the threshold voltage of the non-pixel TFT 35 in the negative direction.

In the first interlayer insulating film 30, the first recessed portion 30A is provided to extend along the second direction that is along the main surface of the non-pixel gate electrode 35A and intersects the first direction, and the first filling portions 39 is provided so as to extend along the second direction. Since the first filling portion 39 that fills the first recessed portion 30A has the surface 39A along the second direction, the light is more efficiently reflected by the surface 39A to be radiated to the portion of the non-pixel semiconductor portion 35D that serves as the channel region. This makes it possible to more efficiently shift the threshold voltage of the non-pixel TFT 35 in the negative direction.

In addition, the non-pixel source electrode 35B and the non-pixel drain electrode 35C extend along the second direction and are drawn to the outside of the non-pixel semiconductor portion 35D. As described above, since the non-pixel source electrode 35B and the non-pixel drain electrode 35C extend in parallel with the first recessed portion 30A and are drawn out to the outside of the non-pixel semiconductor portion 35D, it is possible to prevent the non-pixel source electrode 35B and the non-pixel drain electrode 35C from physically interfering with the first recessed portion 30A and the first filling portion 39.

The non-pixel semiconductor portion 35D is shorter than the non-pixel gate electrode 35A in the first direction. In such a configuration, the light radiated from the lower layer side of the non-pixel gate electrode 35A is less likely to be directly radiated to the non-pixel semiconductor portion 35D. In this regard, by reflecting the light radiated from the lower layer side of the non-pixel gate electrode 35A by the first non-overlapping portion 38B1 including the first filling portions 39, it is possible to efficiently radiate the reflected light to the portion of the non-pixel semiconductor portion 35D that serves as the channel region. This makes it possible to more efficiently shift the threshold voltage of the non-pixel TFT 35 in the negative direction.

The non-overlapping portion 38B includes the second non-overlapping portions 38B2 disposed side by side with the overlapping portion 38A along the second direction that is along the main surface of the non-pixel gate electrode 35A and intersects the first direction. The light can be reflected by also the second non-overlapping portion 38B2 in addition to the first non-overlapping portion 38B1 including the first filling portion 39 to be efficiently radiated to the portion of the non-pixel semiconductor portion 35D that serves as the channel region. This makes it possible to efficiently shift the threshold voltage of the non-pixel TFT 35 in the negative direction.

The non-pixel semiconductor portion 35D is shorter than the non-pixel gate electrode 35A in the second direction. In such a configuration, the light radiated from the lower layer side of the non-pixel gate electrode 35A is less likely to be directly radiated to the non-pixel semiconductor portion 35D. In this regard, by reflecting the light radiated from the lower layer side of the non-pixel gate electrode 35A by the second non-overlapping portion 38B2, the reflected light can be caused to travel along the second direction and can be efficiently radiated to the portion of the non-pixel semiconductor portion 35D that serves as the channel regions. This makes it possible to more efficiently shift the threshold voltage of the non-pixel TFT 35 in the negative direction.

In addition, the non-pixel source electrode 35B and the non-pixel drain electrode 35C are disposed so as to overlap none of both ends 35D2 and 35D3, respectively, of the non-pixel semiconductor portion 35D in the first direction. According to such a configuration, both ends 35D2 and 35D3 of the non-pixel semiconductor portion 35D in the first direction are exposed without being covered by the non-pixel source electrode 35B and the non-pixel drain electrode 35C, respectively. Thus, the light reflected by the first non-overlapping portion 38B1 including the first filling portion 39 can be directly radiated to the end of the non-pixel semiconductor portion 35D in the first direction. This makes it possible to efficiently radiate light to a portion of the non-pixel semiconductor portion 35D sandwiched between the non-pixel source electrode 35B and the non-pixel drain electrode 35C, that is, the portion that serves as the channel region.

The first recessed portion 30A is provided in the first interlayer insulating film 30 so as to extend therethrough, the second recessed portion 29A is provided in the first gate insulating film 29 at a position overlapping the first recessed portion 30A so as to communicate with the first recessed portion 30A, and the non-overlapping portion 38B includes the second filling portion 40 that is continuous with the first filling portion 39 and fills the second recessed portion 29A. As described above, since the second filling portion 40 that fills the second recessed portion 29A is disposed so as to protrude from a surface of the gate insulating film 29 toward the lower layer side, the light radiated from the lower layer side of the non-pixel gate electrode 35A can be efficiently reflected together with the first filling portion 39 to be directed to the portion of the non-pixel semiconductor portion 35D that serves as the channel region. This makes it possible to more efficiently shift the threshold voltage of the non-pixel TFT 35 in the negative direction.

The liquid crystal panel (display device) 11 according to the present embodiment includes the array substrate 21 described above, the display region AA that displays an image, and the non-display region NAA that displays no image is displayed. The gate wiring line (first wiring line) 26 is disposed in the display region AA of the array substrate 21, the circuit portion 14 connected to the gate wiring line 26 is disposed in the non-display region NAA of the array substrate 21, and the non-pixel TFT 35 is included in the circuit portion 14. When the circuit portion 14 operates, a signal is supplied to the gate wiring line 26 disposed in the display region AA of the array substrate 21. In the display region AA of the array substrate 21, a large amount of light for display is present whereas in the non-display region NAA of the array substrate 21, the light is not present as much as in the display region AA. For this reason, in the non-pixel TFT 35 included in the circuit portion 14 disposed in the non-display region NAA of the array substrate 21, the amount of radiated light to the non-pixel semiconductor portion 35D tends to be insufficient. In this regard, since the first filling portion 39 that fills the first recessed portion 30A is disposed so as to protrude from a surface of the first interlayer insulating film 30 toward the lower layer side, the light radiated from the lower layer side of the non-pixel gate electrode 35A can be efficiently reflected to be directed to the portion of the non-pixel semiconductor portion 35D that serves as the channel region. This makes it possible to efficiently shift the threshold voltage of the non-pixel TFT 35 in the negative direction, thereby making the characteristics of the non-pixel TFT 35 less likely to deteriorate. even when the amount of light present in the non-display region NAA of the array substrate 21 is small.

### Second Embodiment

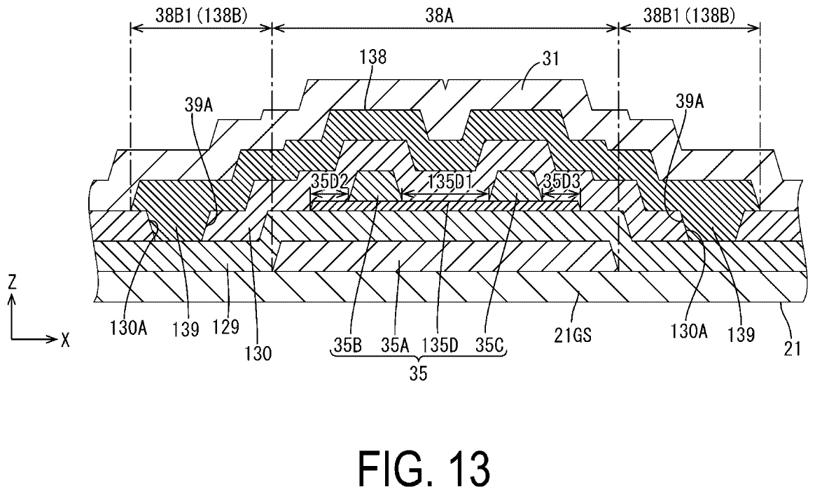

A second embodiment will be described with reference to FIG. 13. In the second embodiment, a case where the second recessed portion 29A and the second filling portion 40 of the first embodiment are omitted will be described. Further, repetitive descriptions of structures, actions, and effects similar to those of the first embodiment described above will be omitted.

As illustrated in FIG. 13, a first recessed portion 130A is provided in a first interlayer insulating film 130 according to the present embodiment. On the other hand, the second recessed portion 29A (see FIG. 6) described in the first embodiment is not provided at a position of a gate insulating film 129 overlapping the first recessed portion 130A. A non-overlapping portion 138B of a light reflective portion 138 includes a first filling portion 139 that fills the first recessed portion 130A, but does not include the second filling portion 40 (see FIG. 6) described in the first embodiment. With such a configuration also, the light radiated from the backlight device can be reflected by the first filling portion 139 that fills the first recessed portion 130A, and the light can be sufficiently and efficiently radiated to a channel forming portion 135D1 of a non-pixel semiconductor portion 135D.

### Third Embodiment

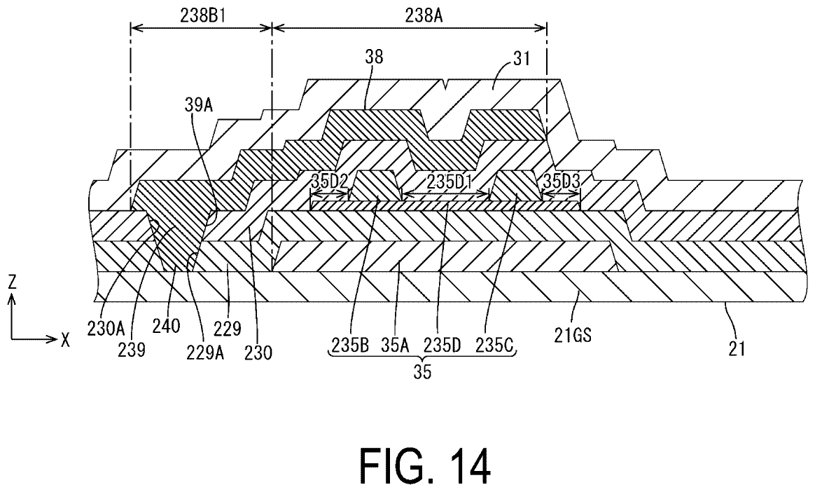

A third embodiment will be described with reference to FIG. 14. In the third embodiment, a case where the numbers of a first recessed portion 230A, a second recessed portion 229A, a first non-overlapping portion 238B1, a first filling portion 239, and a second filling portion 240 are changed from the first embodiment described above will be described. Further, repetitive descriptions of structures, actions, and effects similar to those of the first embodiment described above will be omitted.

As illustrated in FIG. 14, in a first interlayer insulating film 230 and a gate insulating film 229 according to the present embodiment, one first recessed portion 230A and one second recessed portion 229A are provided at a position spaced apart from the non-pixel source electrode 235B on the opposite side to the non-pixel drain electrode 235C side in the X-axis direction. In the first interlayer insulating film 230 and the gate insulating film 229, the first recessed portion 230A and the second recessed portion 229A are not formed at a position on the opposite side to the non-pixel source electrode 235B side in the X-axis direction with respect to the non-pixel drain electrode 235C. The first non-overlapping portion 238B1 is disposed side by side with the overlapping portion 238A only on one side (the left side in FIG. 14) in the X-axis direction, and is not disposed on the other side (the right side in FIG. 14) in the X-axis direction. One first filling portion 239 and one second filling portion 240 are included in a first non-overlapping portion 238B1. The one first filling portion 239 and the one second filling portion 240 fill the one first recessed portion 230A and the one second recessed portion 229A, respectively, disposed in the first interlayer insulating film 230 and the gate insulating film 229. With such a configuration also, the light radiated from the backlight device can be reflected by the first filling portion 239 and the second filling portion 240 that fill the first recessed portion 230A and the second recessed portion 229A, and the light can be sufficiently and efficiently radiated to the channel forming portion 235D1 of the non-pixel semiconductor portion 235D.

### Fourth Embodiment

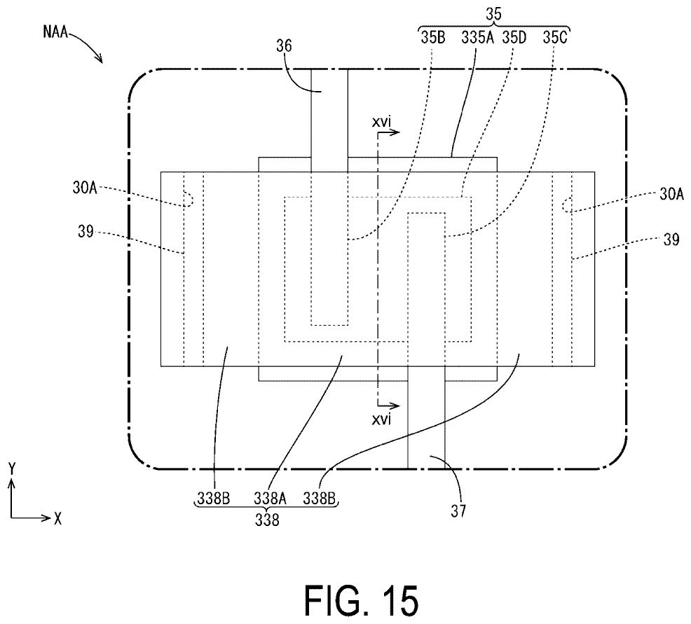

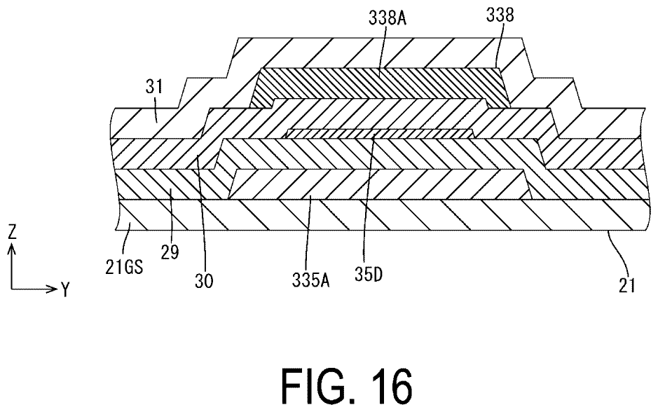

A fourth embodiment will now be described with reference to FIG. 15 or FIG. 16. In the fourth embodiment a case where a size of a light reflective portion 338 is changed from the first embodiment described above will be described. Further, repetitive descriptions of structures, actions, and effects similar to those of the first embodiment described above will be omitted.

As illustrated in FIGS. 15 and 16, the light reflective portion 338 according to the present embodiment has a larger dimension in the X-axis direction but has a smaller dimension in the Y-axis direction than the non-pixel gate electrode 335A. A center-side portion of the light reflective portion 338 in the X-axis direction is an overlapping portion 338A, whereas both end side portions in the X-axis direction are a pair of non-overlapping portions 338B. The non-overlapping portion 338B does not include the second non-overlapping portion 38B2 (see FIG. 7) described in the first embodiment. Both end side portions of the non-pixel gate electrode 335A in the Y-axis direction are exposed without being covered with the light reflective portion 338. With such a configuration also, actions and effects similar to those of the above-described first embodiment can be obtained.

### Fifth Embodiment

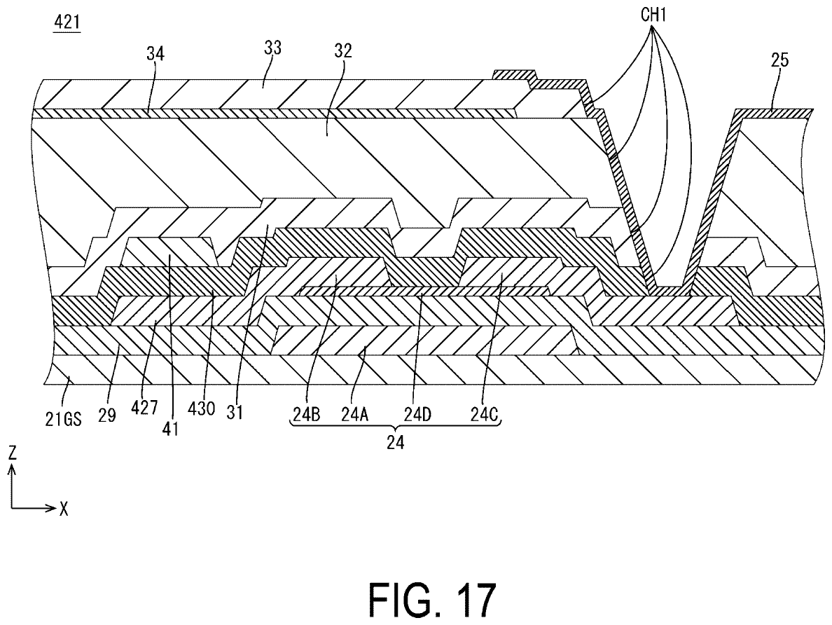

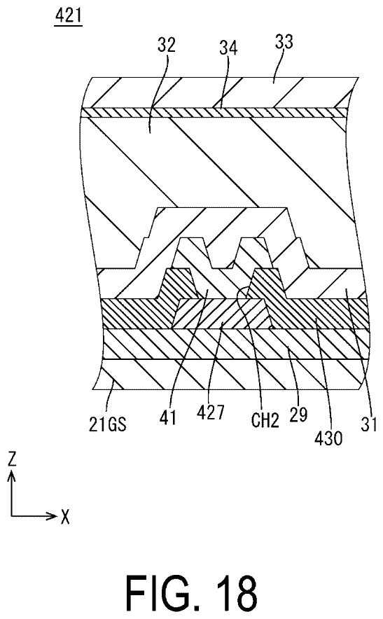

A fifth embodiment will be described with reference to FIGS. 17 and 18. In the fifth embodiment, a case where a configuration of the display region AA of an array substrate 421 is changed from the first embodiment described above will be described. Further, repetitive descriptions of structures, actions, and effects similar to those of the first embodiment described above will be omitted.

As illustrated in FIG. 17, in the display region AA of the array substrate 421 according to the present embodiment, an overlapping wiring line (redundant wiring line, spare wiring line) 41 is disposed to overlap a source wiring line 427. Similarly to the light reflective portion 38 (see FIG. 6), the overlapping wiring line 41 is composed of part of the third metal film. The overlapping wiring line 41 is disposed to overlap the source wiring line 427 on the upper-layer side through a first interlayer insulating film 430. The overlapping wiring line 41 extends in parallel with the source wiring line 427, and overlaps the source wiring line 427 over substantially the entire length. In the first interlayer insulating film 430 interposed between the overlapping wiring line 41 and the source wiring line 427, a source contact hole CH2 is provided to be opened at a position overlapping both the overlapping wiring line 41 and the source wiring line 427. The overlapping wiring line 41 and the source wiring line 427 are connected to each other through the source contact hole CH2. As described above, since the overlapping wiring line 41 in parallel is connected to the source wiring line 427, a wiring line resistance can be reduced, and redundancy at the time of disconnection can be achieved to improve the yield.

### Other Embodiments

The techniques disclosed herein are not limited to the embodiments described above and illustrated in the drawings, and the following embodiments, for example, are also included within the technical scope.
(1) The non-pixel gate electrodes 35A and 335A may be electrically connected to the light reflective portions 38, 138, and 338. In this case, a signal for driving the non-pixel TFT 35 is supplied to the light reflective portion 38, 138, and 338 at the same timing as the non-pixel gate electrodes 35A and 335A. In other words, the light reflective portions 38, 138, and 338 function as “upper-layer side non-pixel gate electrode”, and the non-pixel TFT 35 has a double gate structure. At the time of driving, the channel region is generated in each of the lower layer side (the non-pixel gate electrodes 35A, 335A side) and the upper-layer side (the light reflective portions 38, 138, 338 side) in the Z-axis direction in the non-pixel semiconductor portions 35D, 135D, and 235D.
(2) The non-pixel semiconductor portions 35D, 135D, and 235D may have a larger dimension in the X-axis direction than the non-pixel gate electrodes 35A and 335A. The non-pixel semiconductor portions 35D, 135D, and 235D may have a larger dimension in the Y-axis direction than the non-pixel gate electrodes 35A and 335A.
(3) The non-pixel source electrodes 35B and 235B may cover the ends 35D2 of the non-pixel semiconductor portions 35D, 135D, and 235D. In addition, the non-pixel drain electrodes 35C and 235C may cover the ends 35D3 of the non-pixel semiconductor portions 35D, 135D, and 235D.
(4) The light reflective portions 38, 138, and 338 may be exposed without being covered by the second interlayer insulating film 31.
(5) The first filling portion 39, 139, and 239 may be partially provided in the light reflective portion 38, 138, and 338 in the Y-axis direction. In this case, the first recessed portions 30A, 130A, and 230A may have the same formation ranges in the Y-axis direction as those of the first filling portions 39, 139, and 239, respectively, but may be provided over the entire lengths of the light reflective portions 38, 138, and 338, respectively, in the Y-axis direction. A plurality of the first filling portions 39, 139, and 239 may be provided side by side at intervals in the Y-axis direction.
(6) In the configurations described in the first embodiment and the third to fifth embodiments, the second filling portions 40 and 240 may be partially provided in the light reflective portions 38 and 338 in the Y-axis direction. In this case, the second recessed portion 29A may have the same formation range in the Y-axis direction as that of the second filling portions 40 and 240, but may be provided over the entire lengths of the light reflective portions 38 and 338 in the Y-axis direction. A plurality of the second filling portions 40 and 240 may be provided side by side at intervals in the Y-axis direction.
(7) In the configurations described in the first embodiment and the third to fifth embodiments, the second recessed portion 29A may be provided as a recessed portion that does not extend through the gate insulating films 29 and 229. In this case, the depths of the second recessed portions 29A and the second filling portions 40 and 240 are smaller than the thicknesses of the gate insulating films 29 and 229.
(8) In the configuration described in the second embodiment, the second recessed portion 29A may be provided at a position overlapping any one of the first recessed portions 130A in the gate insulating film 129.
(9) In the configuration described in the second embodiment, the first recessed portion 130A may be provided as a recessed portion that does not extend through the first interlayer insulating film 130. In this case, the depths of the first recessed portion 130A and the first filling portion 139 are smaller than the thickness of the first interlayer insulating film 130.
(10) In the configuration described in the third embodiment, each of the first recessed portion 230A, the second recessed portion 229A, the first filling portion 239, and the second filling portion 240 may be disposed spaced apart from the non-pixel drain electrode 235C on the opposite side to the non-pixel source electrode 235B side in the X-axis direction.
(11) In the configuration described in the fourth embodiment, a magnitude of a difference between a dimension of the light reflective portion 338 in the Y-axis direction and a dimension of the non-pixel gate electrode 335A in the Y-axis direction can be appropriately changed other than the magnitudes illustrated in the drawings. Further, the light reflective portion 338 may be disposed so as to be biased in the Y-axis direction with respect to the non-pixel gate electrode 335A.
(12) In the configuration described in the fifth embodiment, the overlapping wiring line 41 need not be connected to the source wiring line 427. In this case, for example, when a disconnection occurs in the source wiring line 427, the overlapping wiring line 41 may be short-circuited with respect to the source wiring line 427 by performing repair work such as radiation of laser light.
(13) Other than (12) described above, when the liquid crystal panel 11 has a touch panel function, a touch signal may be supplied to the overlapping wiring line 41. In this case, the common electrode 34 may be divided into a plurality of touch electrodes, and the overlapping wiring lines 41 may be connected to the touch electrodes.
(14) The configuration described in the second embodiment can also be appropriately combined with the configurations described in the third embodiment to the fifth embodiment.
(15) The configuration described in the third embodiment can also be appropriately combined with the configuration described in the fourth embodiment or the fifth embodiment.
(16) The configuration described in the fourth embodiment can also be appropriately combined with the configuration described in the fifth embodiment.
(17) In a case where a switch circuit (source shared driving (SSD) circuit) that distributes an image signal supplied from the driver 12 to the plurality of source wiring lines 27 and 427 are provided in the array substrates 21 and 421, respectively, the non-pixel TFT 35 may be included in the switch circuit. In addition, the non-pixel TFT 35 may be provided so as to be included in various circuits provided in the array substrates 21 and 421.
(18) A gate driver may be mounted to the array substrates 21 and 421 instead of the circuit portion 14.
(19) The driver 12 may be mounted by chip on film (COF) on the flexible substrate 13, which is mounted on the array substrates 21 and 421 by film on glass (FOG).
(20) The planar shape of the liquid crystal panel 11 may be a vertically long rectangular shape, a square shape, a circular shape, a semi-circular shape, a vertically long elliptical shape, an oval shape, a trapezoidal shape, or the like.
(21) The material of the semiconductor film provided on the array substrates 21 and 421 may be an amorphous silicon material, a polycrystalline polysilicon material, or the like.
(22) Other than the FFS mode, the display mode in the liquid crystal panel 11 may be a twisted nematic (TN) mode, a vertical alignment (VA) mode, an in plane switching (IPS) mode, or the like.
(23) Other than the liquid crystal panel 11, the display panel as the display device may be an organic electroluminescence (EL) display panel or a microcapsule-type electrophoretic display panel (EPD).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An array substrate comprising:
a transistor including
a first electrode,
a semiconductor portion provided on an upper-layer side of the first electrode and disposed to overlap the first electrode,
a second electrode provided on an upper-layer side of the semiconductor portion and connected to the semiconductor portion, and
a third electrode provided on an upper-layer side of the semiconductor portion, disposed to be spaced apart from the second electrode in a first direction, and connected to the semiconductor portion;
a first insulating film provided on an upper-layer side of the first electrode and on a lower layer side of the semiconductor portion;
a second insulating film provided on an upper-layer side of the second electrode and the third electrode; and
a light reflective portion provided on an upper-layer side of the second insulating film,
wherein the second insulating film is provided with a first recessed portion at a position overlapping none of the first electrode and the semiconductor portion,
the light reflective portion includes
an overlapping portion overlapping the first electrode and the semiconductor portion and
a non-overlapping portion that is continuous with the overlapping portion and overlaps none of the first electrode and the semiconductor portion, and
the non-overlapping portion includes a first filling portion configured to fill the first recessed portion.

2. The array substrate according to claim 1,
wherein the first recessed portion of the second insulating film is provided to be disposed at a position spaced apart from at least one of the second electrode and the third electrode in the first direction,
the non-overlapping portion includes a first non-overlapping portion disposed side by side with the overlapping portion along the first direction, and
the first non-overlapping portion includes the first filling portion.

3. The array substrate according to claim 2,
wherein a pair of the first recessed portions of the second insulating film are respectively provided to be disposed at a position spaced apart from the second electrode in the first direction and at a position spaced apart from the third electrode in the first direction,
a pair of the first non-overlapping portions are disposed to sandwich the overlapping portion in the first direction, and
each of the pair of first non-overlapping portions includes the first filling portion.

4. The array substrate according to claim 2,
wherein the first recessed portion of the second insulating film is provided to extend along a second direction that is along a main surface of the first electrode and intersects the first direction, and
the first filling portion is provided to extend along the second direction.

5. The array substrate according to claim 4,
wherein each of the second electrode and the third electrode extends along the second direction and is drawn out of the semiconductor portion.

6. The array substrate according to claim 2,
wherein the semiconductor portion is shorter than the first electrode in the first direction.

7. The array substrate according to claim 2,
wherein the non-overlapping portion includes a second non-overlapping portion disposed side by side with the overlapping portion along a second direction that is along the main surface of the first electrode and intersects the first direction.

8. The array substrate according to claim 7,
wherein the semiconductor portion is shorter than the first electrode in the second direction.

9. The array substrate according to claim 2,
wherein each of the second electrode and the third electrode is disposed to overlap none of both ends of the semiconductor portion in the first direction.

10. The array substrate according to claim 1,
wherein the first recessed portion is provided in the second insulating film to extend therethrough,
a second recessed portion is provided in the first insulating film at a position overlapping the first recessed portion to communicate with the first recessed portion, and
the non-overlapping portion includes a second filling portion that is continuous with the first filling portion and fills the second recessed portion.

11. A display device comprising:
the array substrate according to claim 1;
a display region configured to display an image;
a non-display region configured to display no image,
wherein a first wiring line is disposed in the display region of the array substrate,
a circuit portion connected to the first wiring line is disposed in the non-display region of the array substrate, and
the circuit portion includes the transistor.
